(19) United States
(12) Patent Application Publication
(10) Pub. No.: US 2026/0119729 A1
(43) Pub. Date: Apr. 30, 2026

(54) BUILDING INFORMATION MODELING SEARCH METHOD, APPARATUS, AND STORAGE MEDIUM

(71) Applicant: TSINGHUA UNIVERSITY, Beijing (CN)

(72) Inventors: Jiarui LIN, Beijing (CN); Shengyu SONG, Beijing (CN); Peng PAN, Beijing (CN)

(73) Assignee: TSINGHUA UNIVERSITY, Beijing (CN)

(21) Appl. No.: 19/142,948

(22) PCT Filed: Dec. 12, 2024
(86) PCT No.: PCT/CN2024/138681

§ 371 Date: Jun. 24, 2025

(30) Foreign Application Priority Data
Dec. 15, 2023 (CN) 202311730705.4

(51) Int. Cl. G06F 30/13; G06F 30/27

(52) U.S. Cl. CPC G06F 30/13; G06F 30/27

(57) ABSTRACT

Provided is a Building Information Modeling (BIM) search method comprising the following steps: performing multimodal feature extraction on the building information models in a model library to be searched, thereby obtaining the corresponding multimodal features for each building information model; acquiring the search text input by the user, parsing the said search text to obtain the search intent information corresponding to it; calculating the comprehensive similarity between the search intent information and the multimodal features of each building information model in the model library to be searched based on deep embedding learning; determining the building information models that serve as the search results corresponding to the search text according to the ranking results of the comprehensive similarity between the search intent information and the multimodal features of each building information model in the model library to be searched, and recommending these search results to the user.

### TECHNICAL FIELD

This disclosure pertains to the field of building information technology, specifically a building information modeling (BIM) search method and apparatus.

### BACKGROUND

Building Information Modeling (BIM) technology enables intuitive three-dimensional visualization of design information, providing efficient solutions for interdisciplinary collaborative design, technical clarification, and whole-process project management of construction projects.

However, research has indicated that current studies lack efficient search methods for complex architectural BIM models. That is, existing BIM model search methods can only search for architectural components (such as walls, doors, windows, beams, etc.) within the models, lacking the capability to consider the characteristics of the overall architectural model (where the overall architecture refers to, for example, a multi-story building encompassing all components across multiple floors and several rooms).

### SUMMARY

In order to address the aforementioned issues, the objective of this disclosure is to provide a building information modeling (BIM) search method and apparatus capable of enabling searches for building information models at the overall architectural level or the level of multi-component assemblies.

To achieve the above objective, this disclosure adopts the following technical solutions.

In the first aspect, this disclosure provides a building information modeling search method, comprising:
performing multimodal feature extraction on building information models at the multi-component assembly level within a model library to be searched, thereby obtaining the corresponding multimodal features for each building information model, wherein the multimodal features comprise semantic features, topological features, and geometric features;
acquiring the search text input by the user, parsing the said search text to obtain the search intent information corresponding to it, wherein the search intent information comprises search intent semantic features, search intent topological features, and search intent geometric features;
calculating the comprehensive similarity between the search intent information and the multimodal features of each building information model in the model library to be searched based on deep embedding learning; and
determining the building information models that serve as the search results corresponding to the search text according to the ranking results of the comprehensive similarity between the search intent information and the multimodal features of each building information model in the model library to be searched, and recommending these search results to the user.

In one implementation of this disclosure, the step of performing multimodal feature extraction on building information models at the multi-component assembly level within a model library to be searched comprises:
extracting the semantic information of the attributes of components at various levels within the building information models at the multi-component assembly level, then summarizing and statistically analyzing the semantic information of the attributes of components at each level to obtain the semantic features of the attributes of the building information models at the multi-component assembly level.

In one implementation of this disclosure, the components at various levels comprise: architectural spaces, walls that can be contained within architectural spaces, and doors or windows that can be contained within walls.

In one implementation of this disclosure, the step of performing multimodal feature extraction on building information models at the multi-component assembly level within a model library to be searched further comprises:
determining the spatial adjacency relationships between architectural spaces based on the attributes of components at various levels, which serve as the topological features of the building information models at the multi-component assembly level.

In one implementation of this disclosure, the spatial adjacency relationships comprise three types: non-adjacent, adjacent but not connected, and connected.

In one implementation of this disclosure, the step of performing multimodal feature extraction on building information models at the multi-component assembly level within a model library to be searched further comprises:
extracting the planar outline information of the building information models as the geometric features of the building information models at the multi-component assembly level.

In one implementation of this disclosure, the step of parsing the search text to obtain the corresponding search intent information comprises:
performing parsing based on text segmentation using natural language processing techniques and regular expressions to obtain the search intent semantic features, search intent topological features, and search intent geometric features of the search intent information.

In one implementation of this disclosure, the step of calculating the comprehensive similarity between the search intent information and the multimodal features of each building information model in the model library to be searched based on deep embedding learning comprises:
embedding the extracted semantic features, topological features, and geometric features of the building information models, as well as the search intent semantic features, search intent topological features, and search intent geometric features, into a unified vectorized representation for similarity calculation.

In one implementation of this disclosure, the similarity calculation is performed using weighted cosine similarity.

In the second aspect, this disclosure provides a building information modeling search apparatus, comprising:
a feature extraction module, configured to perform multimodal feature extraction on building information models at the multi-component assembly level within a model library to be searched, thereby obtaining the corresponding multimodal features for each building information model, wherein these multimodal features comprise semantic features, topological features, and geometric features;
a parsing module, configured to acquire the search text input by the user, parse the said search text to obtain the search intent information corresponding to it, wherein the search intent information comprises search intent semantic features, search intent topological features, and search intent geometric features;
a similarity calculation module, configured to calculate the comprehensive similarity between the search intent information and the multimodal features of each building information model in the model library to be searched based on deep embedding learning;
a recommendation module, configured to determine the building information models that serve as the search results corresponding to the search text according to the ranking results of the comprehensive similarity between the search intent information and the multimodal features of each building information model in the model library to be searched, and visually display these search results to the user.

By adopting the aforementioned technical solutions, this disclosure offers the following advantages: (1) it enables semantic-topological-geometric multimodal feature searches for building-level BIM models; (2) it achieves excellent search results with a significant improvement in accuracy; (3) it optimizes the algorithm's operational efficiency, ensuring a fast search speed.

### BRIEF DESCRIPTION OF THE DRAWINGS

FIG. 1 is a schematic flowchart of the building information modeling (BIM) search method in the embodiments of this disclosure;

FIG. 2 is a flowchart of the semantic feature extraction procedure for model information parsing based on the Industry Foundation Classes (IFC) standard;

FIG. 3 presents an example of attribute information extraction for a building BIM model based on IFC;

FIG. 4 illustrates the processing method for topological connectivity relationships between spatial units such as rooms or courtyards;

FIG. 5 is a flowchart of the topological connectivity feature extraction procedure based on adjacency relationships;

FIG. 6 depicts a method for extracting architectural shape features based on geometric contour data;

FIG. 7 shows a method for extracting planar contour features of each room on every floor of a building BIM model;

FIG. 8 outlines the algorithm flow for extracting planar contour features of a building BIM model;

FIG. 9 presents the search intent parsing process based on text segmentation and regular expressions;

FIG. 10 is a flowchart of the BIM model topological feature embedding based on spatial adjacency and connectivity features;

FIG. 11 is a flowchart of the BIM model shape embedding procedure based on contour and floor plan features;

FIG. 12 is a schematic diagram of the ResNet50 model framework for embedding planar graphic shape features; and

FIG. 13 illustrates the search process for building BIM models based on comprehensive similarity ranking.

### DETAILED DESCRIPTION

In order to make the objectives, technical solutions, and advantages of the embodiments of this disclosure clearer, the technical solutions of the embodiments of this disclosure will be described clearly and completely below in conjunction with the accompanying drawings of the embodiments. It is evident that the described embodiments are part of, but not all, the embodiments of this disclosure. All other embodiments obtained by those of ordinary skill in the art based on the described embodiments of this disclosure fall within the scope of protection of this disclosure.

In response to the problem in the present technology that there is an urgent need to provide a search method for BIM models at the multi-component assembly level (typically, such as the overall architectural level), the technical solution of this disclosure accordingly provides a building information modeling (BIM) search method and apparatus. The method comprises the following steps: performing multimodal feature extraction on building information models at the multi-component assembly level within a model library to be searched, thereby obtaining the corresponding multimodal features for each building information model. These multimodal features comprise semantic features, topological features, and geometric features; acquiring the search text input by the user, parsing the said search text to obtain the search intent information corresponding to it. The search intent information comprises search intent semantic features, search intent topological features, and search intent geometric features; calculating, based on deep embedding learning, the comprehensive similarity between the search intent information and the multimodal features of each building information model in the model library to be searched; determining, according to the ranking results of the comprehensive similarity between the search intent information and the multimodal features of each building information model in the model library to be searched, the building information models that serve as the search results corresponding to the search text, and recommending these search results to the user. This solution enables the search for building information models at the multi-component assembly level.

The additional accompanying drawings of the embodiments of this disclosure for further illustration of the method provided by this disclosure in more detailed embodiments is shown as below.

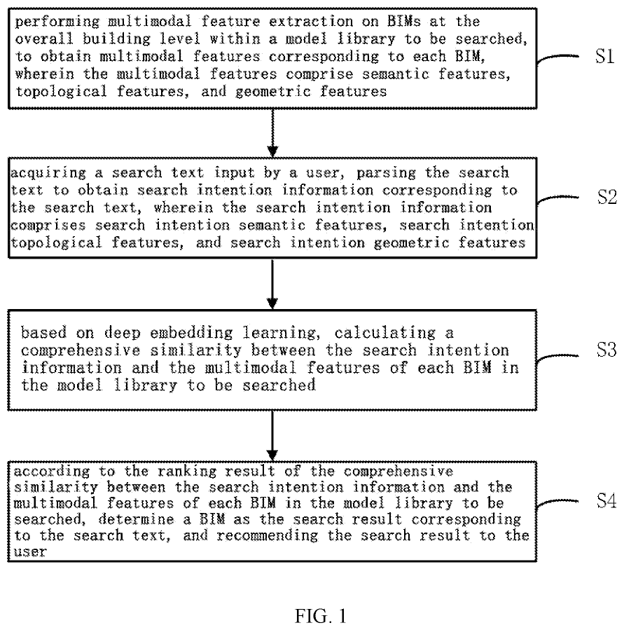

As shown in FIG. 1, this disclosure provides a building information modeling search method, which comprises the following steps:
S1: performing multimodal feature extraction on building information models at the multi-component assembly level within a model library to be searched, thereby obtaining the corresponding multimodal features for each building information model. These multimodal features comprise semantic features, topological features, and geometric features;
S2: acquiring the search text input by the user, parsing the said search text to obtain the search intent information corresponding to it. The search intent information comprises search intent semantic features, search intent topological features, and search intent geometric features;
S3: calculating, based on deep embedding learning, the comprehensive similarity between the search intent information and the multimodal features of each building information model in the model library to be searched; and
S4: determining, according to the ranking results of the comprehensive similarity between the search intent information and the multimodal features of each building information model in the model library to be searched, the building information models that serve as the search results corresponding to the search text, and recommending these search results to the user.

The specific principles and processes of the above method will be illustrated in more detailed embodiments below.

The model search technology in the present technology can only achieve the search for single types of components, whereas the objective of this disclosure is to achieve the search for models composed of multiple components. Multi-component assembly refers to the combination of components at multiple levels. A typical subset of multi-component assembly models is the building information model at the overall architectural level. In disclosure scenarios, an overall building could be, for example, a standalone villa in a rural environment, which comprises multiple levels of architectural spaces. Each level of space can further comprise several different types of rooms, with various components contained within each room. Architectural spaces can also comprise open-air courtyards and other spaces. For ease of illustration, subsequent embodiments may use the search for models at the overall architectural level as an example for elaboration.

The above steps S1 to S4 of the method in this disclosure realize two core contents: S1 realizes the multimodal feature extraction of BIM models at the overall architectural level, while S2 to S4 realize the BIM model similarity retrieval based on deep embedding learning.

The following elaborates on the two aforementioned core contents separately.

### Core Content 1: Multimodal Feature Extraction of BIM Models at the Overall Architectural Level (or Other Multi-Component Assembly Levels)

Multimodal features comprise semantic features, topological features, and geometric features.

Given that existing search algorithms and related deep learning models cannot directly process file formats of architectural BIM models such as RVT and IFC, the first step in searching for BIM models at the overall architectural level is to extract information on attribute texts, topologies, geometries, etc., present within the BIM models. The IFC standard is an open-source BIM standard formulated by the buildingSMART organization, and various open-source parsing tools can be employed to extract information from BIM models in IFC format. For architectural BIM models created using Revit software and exported in the IFC4 model format, this disclosure employs Python scripts for data parsing. Specifically, utilizing the IfcOpenShell tool, components of specified types within the model are traversed and retrieved using the “open” and “by_type” methods. This enables the extraction of geometric shapes of architectural plans, topological connectivity relationships between rooms, attribute information of components such as walls, doors, and windows from the BIM model, thereby forming an automatic extraction algorithm for multiple types of features of the BIM model.

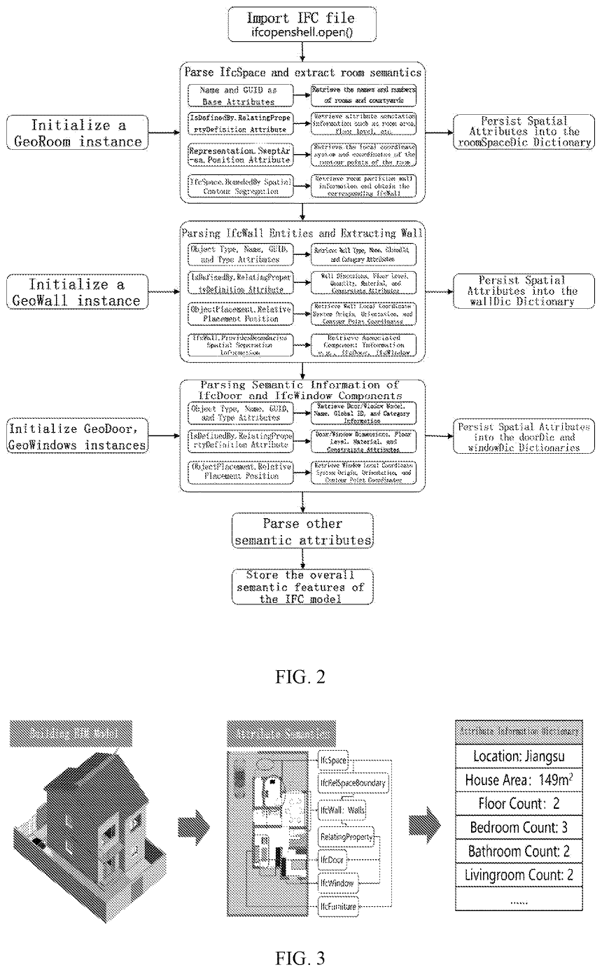

For the semantic features of BIM models at the overall architectural level or other multi-component assembly levels, semantic information of attributes of components at various levels within the building information models at the overall architectural level or other multi-component assembly levels is extracted. Subsequently, the semantic information of attributes of components at each level is aggregated and summarized to obtain the semantic features of attributes of the building information models at the overall architectural level or other multi-component assembly levels, as illustrated in FIG. 2. This specifically comprises:

### Extracting Space (IfcSpace) Attributes:

the IfcSpace class is parsed, which describes information for each space in the apartment layout, to obtain the room name from the basic LongName attribute, the specific floor information where the room is located from the names of associated components of the room, the area information by locating the attribute named “Area” in RelatingPropertyDefinition, the position information of the room from IfcSpace.Representation. Representations. SweptArea, the outline information of the room from BoundedBy, and the separation information between rooms from the ifcRelSpaceBoundary attribute of BoundedBy;

### Extracting Separation Attributes of Walls in Spaces:

IfcWall for each room is extracted to obtain the name and type information of walls within the room, meanwhile, searching for attributes named “Width,” “Length,” “Unconnected Height,” “Bottom Constraint,” and “Dimensioning” in RelatingPropertyDefinition of IfcWall to acquire all attribute information of the wall;

### Extracting Connectivity Attributes of Door and Window Components in Walls:

for each wall, the IfcWindow class associated with the wall is parsed to obtain basic information of all windows and acquiring all attribute information of the windows through RelatingPropertyDefinition related to IfcWindow, similarly, IfcDoor is parsed to obtain basic information of each door and then RelatingPropertyDefinition of IfcDoor is read to acquire attribute information of the door.

### Extracting Other Attribute Information When Necessary:

when necessary, IfcFurniture within IfcSpace is parsed to obtain attribute information of furniture and appliances within the room.

### Text Processing and Aggregation:

attribute texts are preprocessed by removing invalid information, synonym replacement is performed, text expressions are standardized, and dictionaries are created such as roomSpaceDic, wallDic, doorDic, windowDic, and furDic to store the aforementioned attribute semantic information, enabling rapid indexing from corresponding subclasses to the original IFC file data.

### Generating Attribute Semantic Feature Vectors:

After various types of attribute information are extracted, the attribute information of the BIM model is summarized into a specific form of a Python attribute information dictionary according to rules, such as “{Province: Beijing, Area: 219, Cost: 600000, Number of Floors: 3, Number of Rooms: 10, Number of Bedrooms: 4, Number of Bathrooms: 3, Number of Kitchens: 1, . . . }”. Subsequently, the information of a single house is processed into a feature vector according to agreed parameters for subsequent apartment layout queries and matching. The overall process is illustrated in FIG. 3.

For the topological features of BIM models at the overall architectural level or other multi-component assembly levels, the spatial adjacency relationships between architectural spaces are determined and serve as the topological features of the building information models at the overall architectural level or other multi-component assembly levels based on the attributes of components at various levels.

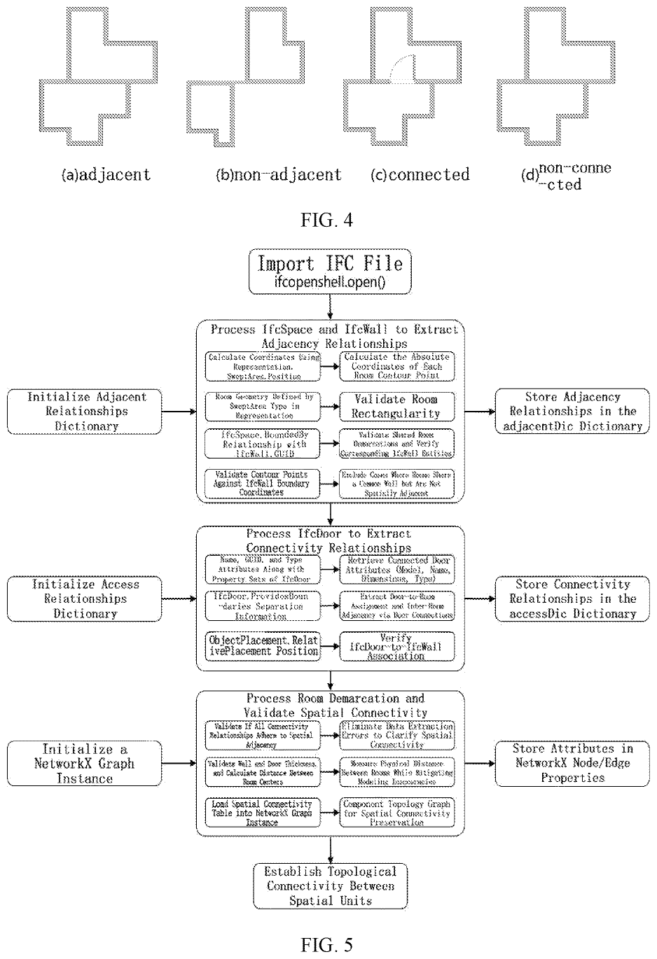

The topological connectivity features of architectural BIM models refer to the relative positional relationships and connection modes between various rooms within the building. This disclosure categorizes the topological relationships between rooms into two types for processing: whether they are adjacent and whether they are connected, as illustrated in FIG. 4. That is, for any two rooms, there are only three possible relationships: non-adjacent, adjacent but not connected, and connected. In BIM models, in addition to walls being capable of separating rooms, Virtual Room Separators can also serve this purpose.

This disclosure distinguishes between physical and virtual room separations by extracting the PhysicalOr VirtualBoundary attribute from IfcRelSpaceBoundary within IfcSpace. The algorithm flow is shown in FIG. 5, with specific steps as follows.

The spatial relationships between room IfcSpace and wall IfcWall is processed to extract adjacency relationships.

### 1.1) Extracting the Spatial Positions of Each Room

By extracting attribute information from IfcSpace, the spatial information of each room is obtained. The local coordinate positions and orientations of rooms are extracted from Representation.SweptArea.Position, along with the relative coordinates of outline points. This allows for the calculation of the absolute coordinate positions of each outline point for every room within the global coordinate system of the entire apartment layout.

1.2) Extracting the Spatial Position Outlines of Each Wall within the Room Space Outlines

By extracting IfcWall, the separation information of each room is obtained. The IfcWall entities on the room's outline can be extracted based on IfcSpace.Boundedby for each room. The absolute coordinates of each boundary point of the wall are calculated through coordinate transformation in ObjectPlacement. RelativePlacement of IfcWall.

### 1.3) Determining Adjacency Relationships Between Rooms

If two IfcSpace rooms share a common IfcWall boundary and there is an overlap in the coordinates of the connecting lines of their outline points, it can be concluded that the two IfcSpace rooms are adjacent. The adjacency relationship is then stored in the adjacentDic dictionary.

From adjacent rooms, the associations between door IfcDoor and rooms and walls are processed to extract connectivity information.

### 2.1) Extracting the Dependency Relationships of Door Components and the Corresponding Room Separation Information

The names and global identifiers of all IfcDoor entities are extracted, followed by the extraction of room information separated by corresponding walls from ProvidesBoundaries of each IfcDoor.

### 2.2) Determining Connectivity Relationships Between Rooms

If the ProvidesBoundaries of an IfcDoor contain two separate IfcSpace rooms, and it can be determined from their RelativePlacement that they share a common IfcWall, and this IfcDoor is located within this IfcWall, then it can be concluded that the two IfcSpace rooms connected in the ProvidesBoundaries of this IfcDoor have a connectivity relationship. This connectivity relationship is then stored in the accessDic dictionary.

Connectivity relationships are verified, organized, and stored.

After the dictionaries of adjacency and connectivity relationships are obtained, it can be verified whether all connectivity relationships satisfy adjacency, and the thicknesses of walls and doors should conform to specified values, thereby excluding the influence of information extraction errors and modeling errors. Finally, the dictionaries are converted into the form of a Networkx topological graph for storage.

Furthermore, the planar outline information of the building information model is extracted as the geometric features of the building information models at the overall architectural level or other multi-component assembly levels.

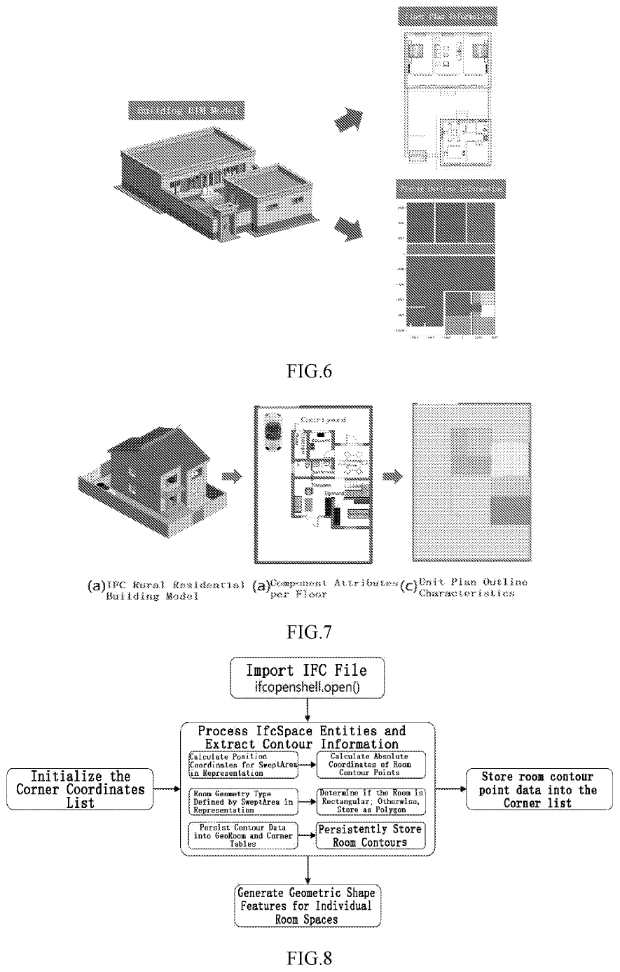

Specifically, unlike attribute information and topological relationships, the geometric shape features of a house involve both two-dimensional (2D) and three-dimensional (3D) information, making it challenging to directly extract information and abstract features through direct parsing of BIM model files. Due to the complexity of 3D geometric features, this disclosure focuses on analyzing the 2D geometric shape features of architectural BIM models. Generally, the geometric features of a house (an instance of the overall architectural-level BIM model in this disclosure) can be determined by the spatial layout and planar outline information of the building. The former can be directly reflected in the floor plan, while the latter can be obtained by extracting a list of coordinates representing the building's outline. Both contain rich geometric information. Therefore, this disclosure comprehensively considers both types of information in the task of extracting geometric features, as illustrated in FIG. 6. The specific steps are as follows.

Wireframe Perspective Floor Plan of Architectural BIM Model is extracted

### 1.1) Capture of Wireframe Floor Plan of Architectural BIM Model

The first-floor floor plan of the BIM model is captured from Revit software as the shape data for the entire apartment layout. By directly adopting the top-down view of the architectural BIM model and fixing the coordinate orientation of the apartment layout, a wireframe-format floor plan is captured to obtain the floor plan information of the apartment.

### 1.2) Image Preprocessing of Wireframe Floor Plan of Architectural BIM Model

The floor plan undergoes image preprocessing to fix the building's orientation, and the dimensions are normalized through scaling for storage.

### 2) Planar Outline Features of Architectural BIM Model are Extracted

### 2.1) Extraction of Room Outline Information of Architectural BIM Model

For the geometric outline information of each room in the architectural BIM model, IfcOpenShell is used to extract the local coordinates of Representation. SweptArea.Position for each room in the apartment layout, forming a list of room outline information.

### 2.2) Conversion of Overall Outline Information of Architectural BIM Model

Using the list of outline information for each room and the information of the local coordinate system, the global coordinates of the overall outline points are calculated in reverse, and a list of overall planar outline data for the architectural BIM model is formed, constructing the external outline data of the overall building, as shown in FIG. 7.

### 2.3) Normalized Storage of Outline Features

The list of coordinates of the external outline points of the overall building is fitted into a polygon with a fixed number of outline points, thereby uniformly storing the external outline point information using a fixed-length vector. The overall algorithm flow is illustrated in FIG. 8.

### Core Content 2: BIM Model Similarity Retrieval Based on Deep Embedding Learning

After multimodal features including attributes, topology, and geometry from architectural BIM models are extracted, the search from text to BIM models necessitates similarity calculation between the search text and BIM models. Therefore, this section first employs natural language processing techniques such as text segmentation and regular expressions to parse the search text and extract the search intent embedded within the natural text. Subsequently, leveraging deep learning and feature engineering tools, the multimodal features of BIM models and the search intent are respectively embedded into the search text and transformed into unified feature vectors. Furthermore, weighted comprehensive similarity calculations are performed based on these feature vectors, enabling intelligent search and recommendation of BIM models through similarity ranking. The detailed steps are introduced in three parts below.

### (1) Search Intent Parsing Based on Text Segmentation and Regular Expressions

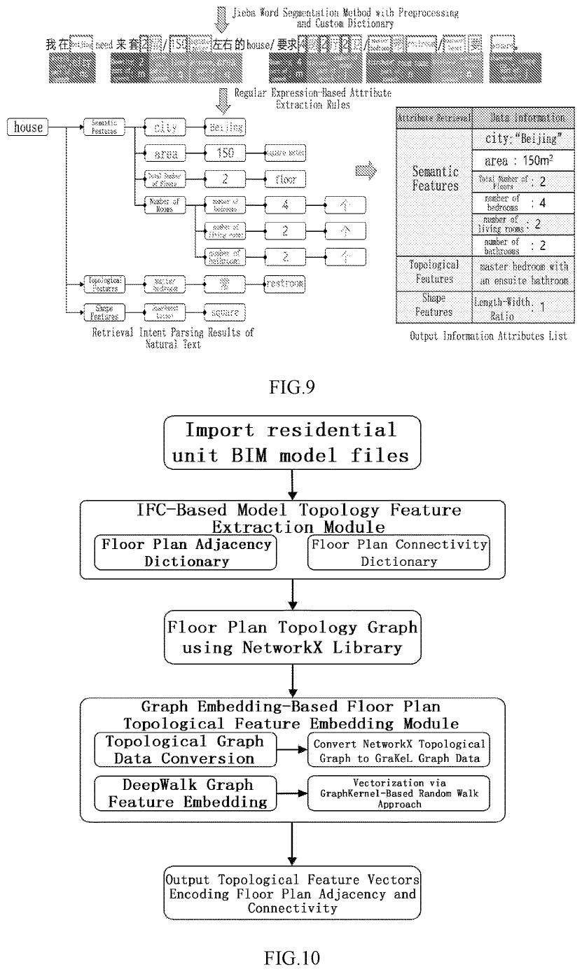

The objective of extracting search intent is to obtain semantic attributes, room topological relationships, geometric descriptions, and other information of the desired BIM model from the textual information, thereby facilitating the query of the target model based on this information. The process is illustrated in FIG. 9, with specific steps outlined as follows.

### 1) Defining a Domain Vocabulary for Architectural BIM Models

Descriptive nouns and common expressions related to the housing and real estate domains are collected to compile and create a domain word list for architectural BIM model searches. This aids in text segmentation and defines the smallest units for proper noun segmentation.

### 2) Domain Text Segmentation Based on the Jieba Library's GRU Neural Network Mode

Jieba is a commonly used open-source Chinese text segmentation disclosure package in Python. Here, search texts are segmented based on the domain vocabulary and Jieba, utilizing Jieba's paddlepaddle mode, which is based on a Gated Recurrent Unit (GRU) neural network. According to the domain word list, search statements are segmented into fragments with word attributes and word order to facilitate subsequent attribute and conjunction matching.

### Search Intent Parsing Based on Regular Expressions

Descriptions of semantic, topological, and geometric features in the search intent are extracted through manually defined regular expressions. Some examples of regular expressions are shown in Table 1. The specific steps are as follows:

TABLE 1

| data type | regex patterns | note |
|---|---|---|
| Integer and | re.findall(r‘\d+\d*’, pseg_cut[i].word) | Extracting data |
| floating-point | re.findall(r‘\d+\.\d+’, pseg_cut[i].word) | attributes such as area |
| number | | and floor |
| keyword | re.findall(fr‘\b(?:{“\|”.join(Keywords)})\b’, | extracting attributes |
| attribute | pseg_cut[i].word) | like province, city, and |
| semantics | | room name |
| topological | re.findall(fr‘\b(?:{“\|”.join(ConnectionWords)})\b’, | Extracting conjunctions |
| relation | pseg_cut[i].word), | and the two spatial - |
| | re.findall(fr‘\b(?:{“\|”.join(RoomName)})\b’, | noun phrases that |
| | pseg_cut[i].word) | connect in natural text |
| shape | re.findall(fr‘\b(?:{“\|”.join(ShapeWords)})\b’, | Extracting simple |
| description | pseg_cut[i].word) | descriptions of |
| | | apartment layout shapes |

### 3.1) Semantic Feature Parsing of Search Intent Based on Regular Expressions

For the attributes and semantic information of the desired BIM model, various descriptive clauses in the search statement are extracted, and keywords such as nouns, verbs, and prepositions are matched according to the syntactic structure. For instance, when “area” and “is” appear, the number following “is” is extracted as the house area for the search. Finally, the corresponding attributes and semantics are summarized into a dictionary.

### 3.2) Topological Feature Parsing of Search Intent Based on Regular Expressions

Using a method similar to 3.1), topological connectivity features of rooms are extracted. For example, from the phrase “living room connected to kitchen,” keywords representing room names, such as “living room” and “kitchen,” as well as the word “connected” indicating connectivity, are extracted to obtain semantic information related to topological connectivity. This information is finally summarized into a connectivity dictionary and a NetworkX network graph.

### 3.3) Geometric Feature Parsing of Search Intent Based on Regular Expressions

For shape features, vague shape descriptions like “square layout” and “narrow and long bedroom” are extracted from the search text to generate a corresponding list of contour features including parameters such as the aspect ratio of the bounding rectangle. This list is finally summarized into a shape attribute dictionary.

### Summary of Search Intent Parsing

Finally, various feature dictionaries extracted using regular expressions are summarized to facilitate subsequent searches.

### (2) Vectorized Representation of Multimodal Features Based on Deep Embedding Learning

After semantic, topological, and geometric feature information is extracted from BIM models, as well as semantic, topological, and geometric features from search intents, they need to be embedded into a unified vectorized representation for similarity calculation. Generally, the semantic information of each attribute is directly organized into a vector composed of uniformly formatted text and data for embedding semantic features. Topological information is stored in the form of a NetworkX topological graph, and graph kernel methods are used to achieve topological feature embedding. For geometric feature embedding, floor plan images are embedded through a convolutional neural network, contour information is embedded through the characteristic parameters of the contour, and geometric shape descriptions in the search text are also embedded as characteristic parameters of the house contour. Specific methods comprise the following.

Embedding of Semantic Features Based on a Combination of Manual Rules and Word2Vec Neural Network

The multimodal feature extraction method for BIM models in Section 5.2.1 can extract semantic attributes of BIM models in the form of “{Province: Jiangsu, Area: 149 square meters, Cost: $100,000, Number of Floors: 2, Number of Bedrooms: 3, Number of Bathrooms: 2, Number of Living Rooms: 1, Number of Kitchens: 1 . . . }”. The search intent extraction method in part (1) of this section can also generate an attribute dictionary in a corresponding format. Word2Vec is a class of neural network models commonly used in natural language processing tasks to convert words into word-based vectors. This disclosure uses manually defined conversion rules in combination with the Word2Vec neural network to embed the attribute dictionary into a semantic feature vector. The processing method is referenced in Table 2, with specific steps outlined as follows.

TABLE 2

| | data | | |
|---|---|---|---|
| attribute name | type | data example | embedding method |
| room name | String | Master Bedroom, | Word2Vec word |
| | | Living Room etc. | vectors |
| gross area | Float | 100 m², 135 m²etc. | normalized relative |
| | | | value |
| number of floors | Integer | second floor, third | normalized relative |
| | | floor etc. | value |
| number of | Integer | 3-bedroom, | normalized relative |
| bedrooms | | 5-bedroom etc. | value |
| the province of | String | Beijing, Jiangsu etc. | weighted matching |
| residence | | | list |
| the city where | String | Nanjing, Suzhou etc. | weighted matching |
| one is located | | | list |
| room function | String | Kitchen, washroom | Word2Vec word |
| | | | vectors |

### 1.1) Standardization of Synonyms and Near-Synonyms

Specifically, for synonyms and near-synonyms that may widely exist in the semantic dictionary, such as “bathroom,” “washroom,” “sanitary,” and “toilet,” a manual list of synonyms and near-synonyms is defined, and their descriptions are unified into the same descriptive dictionary for synonym replacement.

### 1.2) Embedding of Attribute Data Features Based on Manual Rules

For data information within attributes, detailed comparisons can be directly conducted through numerical differences, making the embedding process relatively straightforward. After weighting and normalizing the data attributes, manual rules are employed to embed different types of data according to their characteristic features.

### 1.3) Embedding of Attribute Semantic Features Based on Word2Vec

For semantic information within attributes, the text is typically in the form of string attributes, which need to be embedded as string vectors and then further embedded using the Word2Vec model. Specifically, the Word2Vec model is implemented using the Gensim package, a popular Python library for natural language processing. Based on the synonym list defined in 1.1), a corresponding text corpus is constructed as a training set. Using this corpus, the Word2Vec model is trained with the parameters “vector_size=100, window=5, min_count=1, worker=4.”

### 1.4) Feature Embedding of Mixed Data and Semantics

Other types of semantic information are categorized into textual information and data information according to predefined rules. They are embedded as string word vectors and data vectors, respectively, and then weighted and combined as feature vectors. The corresponding weights are manually determined by experts.

### Embedding of Topological Features Based on Graph Neural Networks

The spatial topological relationships previously extracted from BIM models and search texts can be converted into NetworkX topological graphs for storage. Graph kernels are an effective method for graph feature embedding in graph neural networks. Therefore, the Deepwalk deep random walk method based on graph kernels is chosen to embed topological features. This method is unsupervised, has better transferability, and is more suitable for the graph data in this disclosure. Its program flow is illustrated in FIG. 10, with specific embedding methods outlined as follows.

2.1) Conversion of Topological Graphs into Network Graphs Based on NetworkX and Grakel

The NetworkX library is a commonly used open-source Python library for storing and sharing graph data formats, while Grakel is a commonly used open-source Python library for graph kernel machine learning tasks in graph convolution. Here, the implementation is based on NetworkX and Grakel. Using the node list, node attribute list, and adjacency matrix of the NetworkX topological graph, the Grakel.graph method is used to convert the NetworkX topological graph into Grakel graph network data.

### 2.2) Vectorization of Network Graph Features Based on Random Walk Kernels

Through random walks, with the same Graph Kernel fixed, the Grakel graph network is embedded into topological feature vectors using the Grakel. GraphKernel method. After weighted normalization, topological feature vectors of BIM models are obtained that measure the similarity of the overall connectivity relationships of apartment layouts.

### Embedding of Geometric Shape Features Based on Contour Visual Features and Convolutional Neural Networks

Previously, the geometric shape information of BIM models has been divided into contour data information and floor plan data information for processing. Therefore, two types of features are embedded separately to complement each other. The geometric contours extracted from BIM models not only contain information about the overall external outline of the apartment layout but also comprise the positional information of each type of room on the plane. Therefore, shape description features can be directly constructed based on the overall planar contour information of the apartment layout to vectorize its shape. Meanwhile, using a convolutional neural network, feature vectors of the apartment layout shape are extracted from its floor plan, thereby eliminating the influence of noise and transformations from a single contour feature and vectorizing the overall planar layout shape of the apartment. Its embedding flow is illustrated in FIG. 11, with specific embedding methods outlined as follows.

### 3.1) Extraction of Geometric Contour Features Based on Contour Visual Features

The OpenCV computer vision toolkit is used to extract features from the previously extracted BIM model contour information. Indicators describing the shape of the apartment layout and its internal rooms comprising the aspect ratio of the bounding rectangle, the area ratio between the contour and the bounding rectangle, the centroid coordinates of the apartment layout, and the information coordinates of each room, are calculated based on the contour information. These data are then normalized to form descriptive indicators of the apartment layout's shape features based on geometric contours, as shown in Table 3. The specific steps are as follows.

TABLE 3

| feature | | | embedding |
|---|---|---|---|
| type | metric parameter | computational method | method |
| outer | outer contour fitting to | Fit the outer contour polygon with 30 | fixed-length |
| contour | a polygon | points as specified | vector |
| unit layout | The length - to - width | Calculate the aspect ratio of the | floating-point |
| shape | ratio of the apartment | bounding rectangle of the outer contour | number |
| | layout | | |
| | Image Moments of the | Calculate the centroid, moment of | fixed-length |
| | Apartment Layout | inertia, etc. of the apartment layout using | vector |
| | | the outer - contour points | |
| | Area Ratio of the | The Area Ratio between the Outer | floating-point |
| | Apartment Layout | Contour and the Bounding Rectangle of | number |
| | | the Apartment Layout | |
| | Parameters of the Fitted | The Major and Minor Axis Vectors of | fixed-length |
| | Ellipse for the | the Ellipse Fitted to the Outer Contour | vector |
| | Apartment Layout | | |
| subdivided | The Length - to - Width | The Average Length - to - Width Ratio | floating-point |
| space shape | Ratio of the Bedroom | of the Minimum Bounding Rectangles of | number |
| | | Each Bedroom's Contour | |
| | The Length - to - Width | The Average Length - to - Width Ratio | floating-point |
| | Ratio of the Living | of the Minimum Bounding Rectangles | number |
| | Room | Enclosing Each Living Room's Contour | |
| | The Length - to - Width | The Average Length - to - Width Ratio | floating-point |
| | Ratio of the Kitchen | of the Minimum Bounding Rectangles | number |
| | | Encompassing Each Kitchen's Contour | |
| | The Length - to - Width | The Average Length - to - Width Ratio | floating-point |
| | Ratio of the Courtyard | of the Minimum Bounding Rectangles | number |
| | | Encompassing Each Courtyard's Contour | |

### 3.1.1) Fitting and Embedding of Outer Contour Coordinates for Architectural BIM Models

Using the cv2.approxPolyDP method for polygon fitting, with the number of contour points for the polygon fixed at 30, the outer contour of the apartment layout is fitted into a 30-sided polygon. This normalizes the outer contour coordinates, forming a fixed-length vector of contour points and thus embedding the outer contour information.

### 3.1.2) Embedding of Aspect Ratio Features for Architectural BIM Model Contours

The cv2. boundingRect method is used to calculate the bounding rectangle of the contour. The aspect ratio of this rectangle is used to measure the squareness of the overall planar shape of the architectural BIM model, which is then embedded in the form of a floating-point number.

### 3.1.3) Embedding of Image Moment Features for Architectural BIM Model Contours

The cv2.moments method is used to calculate the image moments of the apartment layout contour, from which features such as the centroid, moments of inertia, and third-order moments of the architectural BIM model are characterized.

### 3.1.4) Embedding of Ellipse Fitting Features for Architectural BIM Models

Considering the existence of apartment layouts with relatively narrow and long shapes, an ellipse fitting method is employed to embed their shape features. The cv2.fitEllipse method is used to find the ellipse closest to the architectural contour, and the major and minor axis vector features of the ellipse are extracted and embedded in the form of a fixed-length vector.

### 3.1.5) Embedding of Shape Features for Internal Subdivided Spaces in Architectural BIM Models

For the shapes of subdivided spaces such as rooms and courtyards within the architectural BIM model, the squareness is measured by the average aspect ratio of the bounding rectangles of these spaces within the apartment layout. The cv2.boundingRect method is used to calculate the average aspect ratio information for each bedroom, living room, kitchen, and courtyard separately, forming four categories of aspect ratio features for subdivided spaces, which are then embedded in the form of floating-point numbers.

### 3.2) Embedding of Floor Plan Data Information Based on Convolutional Neural Networks

For feature extraction from the floor plans of architectural BIM models, this disclosure introduces feature engineering techniques based on convolutional neural network to extract the overall geometric features of the floor plan by using a pre-trained ResNet50 model, as detailed below.

### 3.2.1) Selection of Convolutional Neural Network Structure

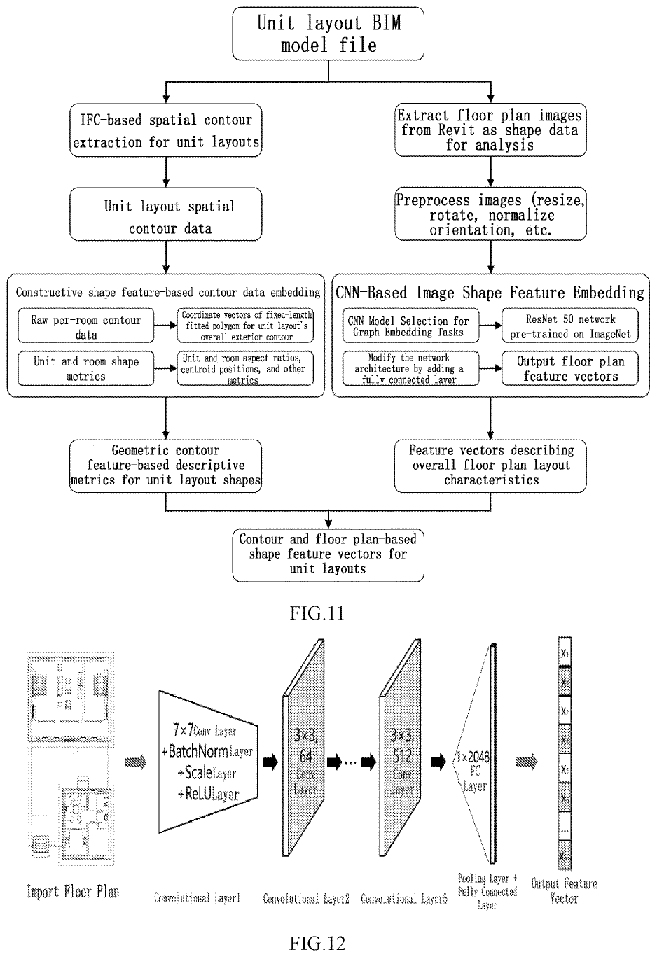

In the selection and construction of the convolutional neural network model, the ResNet50 neural network is chosen. The input and output layer structures of the neural network are adjusted to uniformly accept three-channel images in a 224×224 format and output 2048-dimensional image shape feature vectors. The neural network structure is illustrated in FIG. 12.

### 3.2.2) Embedding of Floor Plan Data Based on Pre-Trained Models

The widely used ImageNet dataset is selected for pre-training the ResNet50 network structure. A model is generated based on the pre-trained CheckPoint weights from the ImageNet dataset. By running this model and extracting data from the fully connected layer, a 2048-dimensional image shape feature vector for the floor plan can be output.

### 3.3) Integration of Contour and Floor Plan Feature Embeddings for Architectural BIM Models

The aforementioned floor plan feature vectors are weighted and combined with the feature indicators of the architectural BIM model contours, forming a comprehensive shape feature vector that integrates data from both the apartment layout contour and floor plan shape features. The weights for these two types of feature embeddings are manually determined by experts and adjusted through three rounds of manual refinement based on performance.

### (3) Architectural BIM Model Search Based on Comprehensive Similarity Ranking

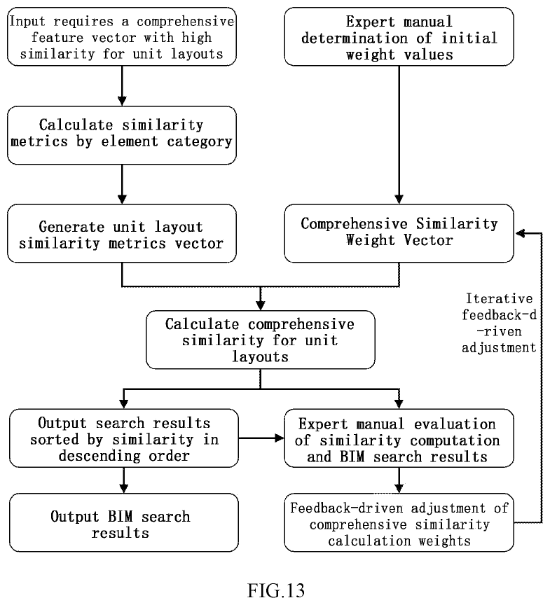

Previously, a unified vectorized embedding method for the semantic, topological, and geometric multimodal features of BIM models, as well as search intent information, has been realized. To perform a text-to-BIM model search, this subsection calculates comprehensive similarity based on the feature vectors of BIM models and search intents, and retrieves BIM models through weighted cosine similarity ranking. The overall process is illustrated in FIG. 13, with specific methods outlined as follows.

### 3.1) Determination of Various Similarity Evaluation Metrics

By calculating the weighted cosine similarity of feature vectors, it is straightforward to compare the similarity between BIM models and between text and BIM models, enabling intelligent retrieval of BIM models through similarity ranking. However, the elements of feature vectors have different compositions, magnitudes, and meanings. Therefore, it is necessary to use appropriate similarity evaluation metrics to calculate the similarity of different elements of the vectors. The processing methods for several typical similarity metrics are shown in Table 4, as detailed below:

TABLE 4

| feature | element | data | Description of | Similarity |
|---|---|---|---|---|
| category | category | format | element characteristics | measure |
| semantic | Category | String | City, Province etc. | Character matching |
| features | attribute | | | rate |
| | Descriptive | word vector | Name, Room Function | Vector Cosine |
| | attribute | | etc. | Similarity |
| | floating-point | Float | 100 m², 135 m² etc. | Relative deviation |
| | quantitative | | | |
| | attribute | | | |
| | integer | Integer | second floor, third floor | Relative deviation |
| | quantitative | | etc. | |
| | attribute | | | |
| topological | topological | fixed-length | eigenvector of a | Vector Cosine |
| features | feature vector | vector | topological graph | Similarity |
| | contour point | coordinate | coordinate list for contour | Contour Hu |
| | coordinates | vector | fitting | Moments |
| | | | | Similarity |
| geometric | shape image | fixed-length | image distance of | Vector Cosine |
| features | moments | vector | apartment layout shape | Similarity |
| | fitted shape | fixed-length | Major and minor axes of | Vector Cosine |
| | parameters | vector | the fitted ellipse | Similarity |
| | floating-point | Float | such as the aspect ratio, | Relative deviation |
| | quantitative | | area ratio, etc. | |
| | indicator | | | |

### 3.1.1) Similarity Metrics for String Elements

For string elements, such as location and room names, the character matching rate is used as a measure of similarity. For floating-point and integer-quantified elements, such as bedroom areas and quantities, relative differences are used to measure similarity.

### 3.1.2) Similarity Metrics for Sub-vector Elements

For sub-vector elements with specific meanings, such as word vectors for topological graphs, fitted rectangular features, and image moments of shapes, similarity is also measured by taking the cosine similarity of the sub-vectors.

### 3.1.3) Similarity Metrics for Coordinate List Elements

For coordinate list elements, such as the list of fitted outer contour coordinates in shape features, the cv2.matchShapes method from OpenCV is introduced to compare the similarity of contours based on the relative differences of their Hu moments.

### 3.2) Determination of Integrated Weights for Detailed Metrics

In addition to similarity metrics, another key focus in calculating comprehensive similarity is determining the weights for each type of feature. Considering the size of the search dataset, this study uses manual feedback adjustment by experts to establish the weights, as detailed below.

### 3.2.1) Determination of Initial Weights

Initial weights are first manually determined by experts. The BIM model search results are then sorted in descending order based on comprehensive similarity, forming a list of search results.

### 3.2.2) Weight Adjustment Based on Manual Feedback

The weights for comprehensive similarity are feedback-adjusted through manual evaluation of search results by experts. After more than 10 rounds of manual comparison and adjustment, the comprehensive similarity results meet the corresponding expert evaluations.

### 3.2.3) Derivation of Final Weights and Formation of Similarity Ranking Algorithm

The percentage weights for semantic features are approximately 88%, topological features are 5%, and geometric features are 7%. By sorting based on the weighted cosine similarity of feature vectors, a corresponding BIM gallery search ranking algorithm is formed, which has the advantage of fast computation speed and can optimize search results by adjusting weights.

In summary, the method of this disclosure achieves the following effects.
(1) It realizes semantic-topological-geometric multimodal feature search for BIM models at the overall building level or multi-component combination level, supporting large-scale and wide-ranging model searches. Based on IfcOpenShell, it extracts and deeply embeds semantic, topological connectivity, and shape features of overall building BIM models, expanding the applicable model scale of BIM model search algorithms to the overall building level for the first time and realizing similarity search for three types of features—semantic, topological, and geometric—from text to architectural BIM models for the first time.
(2) While ensuring (1), it achieves good search results with significantly improved accuracy. By introducing deep embedded learning and embedding multimodal features of “semantic-topological-geometric,” an intelligent retrieval algorithm for architectural-level BIM atlases based on comprehensive similarity is developed. The corresponding intelligent search method has been well-validated in typical engineering projects. In terms of search accuracy and ranking effectiveness, the mNDCG1 and mNDCG5 indicators of the algorithm in the test set both reach around 90%, achieving almost the same retrieval quality and effectiveness as manual expert retrieval. Compared with traditional retrieval algorithms that only consider semantics, the search effectiveness is significantly improved by more than 6.5%, enabling good atlases to be found not only but also accurately, comprehensively, and effectively.
(3) While ensuring the search quality of (1) and (2), it optimizes the algorithm's operational efficiency and guarantees search speed. In the test set, under the premise of ensuring retrieval effectiveness, the average time taken by three experts to retrieve 50 search queries is 1740 seconds, while this disclosure can achieve similar retrieval quality to expert searches, and the algorithm can run smoothly on an ordinary civilian laptop, taking only 2.23 seconds (with a hardware environment of M1 Pro and 16 GB memory). The retrieval efficiency is hundreds of times higher than manual retrieval, with the total time consumption reduced by nearly three orders of magnitude. Therefore, in disclosure environments where retrieval quality is guaranteed, this disclosure can significantly reduce manual labor, allowing experts and designers to focus more on higher-difficulty manual tasks.

Another aspect of this disclosure provides a building information model search device, comprising:
a feature extraction module for extracting multimodal features from building information models at the overall building level or multi-component combination level in a model library to be searched, obtaining the corresponding multimodal features for each building information model, the multimodal features comprise semantic, topological, and geometric features.
a parsing module for obtaining search text input by users, parsing the search text to obtain the corresponding search intent information, which comprises search intent semantic features, search intent topological features, and search intent geometric features;
a similarity calculation module for calculating the comprehensive similarity between the search intent information and the multimodal features of each building information model in the model library to be searched based on deep embedded learning; and
a recommendation module for determining the building information models corresponding to the search results of the search text based on the ranking results of the comprehensive similarity between the search intent information and the multimodal features of each building information model in the model library to be searched, and recommending the search results to users.

Embodiments of this disclosure also provide a computer-readable storage medium that comprises stored programs. When the programs are run, they control the device where the storage medium is located to execute the aforementioned methods. The specific implementation process is not repeated here.

Embodiments of this disclosure also provide a computer device. The computer device of this embodiment comprises a processor, a memory, and a computer program stored in the memory and executable on the processor. When the processor executes the computer program, it implements the aforementioned methods in the embodiments. To avoid repetition, these are not elaborated one by one here. Alternatively, when the computer program is executed by the processor, it implements the functions of the models/units in the device in the embodiments. To avoid repetition, these are not elaborated one by one here.

The computer device can be a desktop computer, laptop, palmtop computer, server, cloud server, or other computing device. The computer device may comprise, but is not limited to, a processor and a memory. Those skilled in the art can understand that it may comprise more or fewer components than shown, or some components may be combined, or different components may be used. For example, the computer device may also comprise input/output devices, network access devices, buses, etc.

The so-called processor can be a Central Processing Unit (CPU), or other general-purpose processors, Digital Signal Processors (DSPs), Application Specific Integrated Circuits (ASICs), Field-Programmable Gate Arrays (FPGAs), or other programmable logic devices, discrete gate or transistor logic devices, discrete hardware components, etc. The general-purpose processor can be a microprocessor or any conventional processor, etc.

The memory can be an internal storage unit of the computer device, such as a hard disk or memory of the computer device. The memory can also be an external storage device of the computer device, such as a plug-in hard disk, Smart Media Card (SMC), Secure Digital (SD) card, Flash Card, etc., equipped on the computer device. Furthermore, the memory can comprise both internal storage units and external storage devices of the computer device. The memory is used to store computer programs and other programs and data required by the computer device. The memory can also be used to temporarily store data that has been output or is about to be output.

Those skilled in the art can clearly understand that, for the convenience and conciseness of description, the specific working processes of the aforementioned systems, devices, and units can be referred to the corresponding processes in the aforementioned method embodiments and are not repeated here.

In the several embodiments provided by this disclosure, it should be understood that the disclosed systems, devices, and methods can be implemented in other ways. For example, the aforementioned device embodiments are merely illustrative. For example, the division of the aforementioned units is merely a logical function division, and there can be other division methods in actual implementation. For example, multiple units or components can be combined or integrated into another system, or some features can be ignored or not executed. In addition, the displayed or discussed mutual coupling or direct coupling or communication connection can be an indirect coupling or communication connection through some interfaces, devices, or units, and can be in electrical, mechanical, or other forms.

The integrated units implemented in the form of software functional units can be stored in a computer-readable storage medium. The aforementioned software functional units are stored in a storage medium and comprise several instructions to enable a computer device (which can be a personal computer, server, or network device, etc.) or a processor to execute some steps of the aforementioned methods in each embodiment of this disclosure. The aforementioned storage medium comprises various media that can store program codes, such as U disks, mobile hard disks, Read-Only Memory (ROM), Random Access Memory (RAM), magnetic disks, or optical disks.

The above are merely preferred embodiments of this disclosure and are not intended to limit this disclosure. Any modifications, equivalent substitutions, improvements, etc., made within the spirit and principles of this disclosure should be comprised within the protection scope of this disclosure.

1. A building information modeling (BIM) search method, wherein the method comprises:
performing multimodal feature extraction on BIMs at the multi-component assembly-level in a model library to be searched, to obtain multimodal features corresponding to each BIM, wherein the multimodal features comprise semantic features, topological features, and geometric features;
acquiring a search text input by a user, parsing the search text to obtain search intention information corresponding to the search text, wherein the search intention information comprises search intention semantic features, search intention topological features, and search intention geometric features;
calculating a comprehensive similarity between the search intention information and the multimodal features of each BIM in the model library to be searched based on deep embedding learning; and
determining a BIM as the search result corresponding to the search text according to the ranking result of the comprehensive similarity between the search intention information and the multimodal features of each BIM in the model library to be searched, and recommending the search result to the user.

2. The BIM search method according to claim 1, wherein the performing multimodal feature extraction on BIMs at the multi-component assembly level in the model library to be searched comprises:
extracting semantic information of the attributes of components at various levels in the BIMs at the multi-component assembly level, and then summarizing and counting the semantic information of the attributes of the components at various levels to obtain semantic features of the attributes of the BIMs at the multi-component assembly level.

3. The BIM search method according to claim 2, wherein the components at various levels comprise: architectural spaces, walls that can be contained within the architectural spaces, and doors or windows that can be contained within the walls.

4. The BIM search method according to claim 3, wherein the method performing multimodal feature extraction on BIMs at the multi-component assembly level in the model library to be searched further comprises:
determining spatial adjacency relationships between architectural spaces as topological features of the BIMs at the multi-component assembly level according to the attributes of the components at various levels.

5. The BIM search method according to claim 4, wherein the spatial adjacency relationships comprise three types: non-adjacent, adjacent but not connected, and connected.

6. The BIM search method according to claim 2, wherein the performing multimodal feature extraction on BIMs at the multi-component assembly level in the model library to be searched further comprises:
extracting planar contour information of the BIMs as geometric features of the BIMs at the multi-component assembly level.

7. The BIM search method according to claim 1, wherein the parsing the search text to obtain the search intention information corresponding to the search text comprises:
performing parsing based on text segmentation using natural language processing and regular expressions to obtain search intention semantic features, search intention topological features, and search intention geometric features of the search intention information.

8. The BIM search method according to claim 7, wherein the calculating a comprehensive similarity between the search intention information and the multimodal features of each BIM in the model library to be searched based on deep embedding learning comprises:
embedding the extracted semantic features, topological features, and geometric features of the BIMs, as well as the search intention semantic features, search intention topological features, and search intention geometric features of the search intention, into a unified vectorized representation for similarity calculation.

9. The BIM search method according to claim 8, wherein the similarity calculation is a weighted cosine similarity calculation.

10. A BIM search device, comprising:
a feature extraction module, configured to perform multimodal feature extraction on BIMs at the multi-component assembly level in a model library to be searched, to obtain multimodal features corresponding to each BIM, wherein the multimodal features comprise semantic features, topological features, and geometric features;
a parsing module, configured to acquire a search text input by a user, parse the search text to obtain search intention information corresponding to the search text, wherein the search intention information comprises search intention semantic features, search intention topological features, and search intention geometric features;
a similarity calculation module, configured to calculate a comprehensive similarity between the search intention information and the multimodal features of each BIM in the model library to be searched based on deep embedding learning; and
a recommendation module, configured to determine a BIM as the search results corresponding to the search text according to the ranking result of the comprehensive similarity between the search intention information and the multimodal features of each BIM in the model library to be searched, and visually display the search result to the user.

11. A computer-readable storage medium, wherein it stores a computer program, and when executed by a processor, it controls the device where the processor is located to implement the following BIM search method:
performing multimodal feature extraction on BIMs at the multi-component assembly level in a model library to be searched, to obtain multimodal features corresponding to each BIM, wherein the multimodal features comprise semantic features, topological features, and geometric features;
acquiring a search text input by a user, parsing the search text to obtain search intention information corresponding to the search text, wherein the search intention information comprises search intention semantic features, search intention topological features, and search intention geometric features;
calculating a comprehensive similarity between the search intention information and the multimodal features of each BIM in the model library to be searched based on deep embedding learning; and
determining a BIM as the search result corresponding to the search text according to the ranking result of the comprehensive similarity between the search intention information and the multimodal features of each BIM in the model library to be searched, and recommending the search result to the user.
